(19) United States
(12) Patent Application Publication
(10) Pub. No.: US 2025/0271604 A1
(43) Pub. Date: Aug. 28, 2025

(54) OPTICAL FILTER, METHOD OF MANUFACTURING OPTICAL FILTER, OPTICAL FILTER UNIT, METHOD OF MANUFACTURING OPTICAL FILTER UNIT, AND OPTICAL MEASUREMENT APPARATUS

(71) Applicant: KONICA MINOLTA, INC., Tokyo (JP)

(72) Inventors: Seiji SOWA, Tokyo (JP); Katsutoshi TSURUTANI, Osaka (JP); Junichi YAMAZOE, Osaka (JP)

(73) Assignee: KONICA MINOLTA, INC., Tokyo (JP)

(21) Appl. No.: 19/050,397

(22) Filed: Feb. 11, 2025

(30) Foreign Application Priority Data
Feb. 27, 2024 (JP) 2024-027399

(51) Int. Cl. G02B 5/20

(52) U.S. Cl. CPC G02B 5/20

(57) ABSTRACT

There is provided an optical filter having a light transmittance characteristic or a light reflectance characteristic for a predetermined wavelength range. The optical filter includes a first optical function layer and a second optical function layer each having a transmittance that varies in a polarization direction of linearly polarized light at vertical incidence. The first optical function layer and the second optical function layer each have a high transmittance axis that is determined by a polarization direction in which transmittance of linearly polarized light at vertical incidence is greatest. The first optical function layer and the second optical function layer are disposed such that an angle formed by the high transmittance axis of the first optical function layer and the high transmittance axis of the second optical function layer is within a range of 90°±30°.

### CROSS-REFERENCE TO RELATED APPLICATIONS

The entire disclosure of Japanese Patent Application No. 2024-027399 filed on Feb. 27, 2024, is incorporated herein by reference in its entirety.

### BACKGROUND OF THE INVENTION

### Technical Field

The present invention relates to an optical filter, a method of manufacturing an optical filter, an optical filter unit, a method of manufacturing an optical filter unit, and an optical measurement apparatus.

### Description of Related Art

An optical measurement apparatus is capable of measuring brightness and chromaticity of light emitted by a measurement target (e.g., a smartphone display, a liquid crystal monitor) (Japanese Patent No. 5454675). The optical measurement apparatus splits the light from the measurement object into beams for measurement.

These days, the display of a device, such as a smartphone, has a wide brightness dynamic range. Therefore, an optical measurement apparatus capable of measuring both bright and dim lights in gamma inspection/adjustment is awaited. To widen the dynamic range of an optical measurement apparatus, the amount of received light is to be regulated. To regulate the amount of received light, a known method uses a thin film filter having spectral flatness and transmittance that does not greatly vary depending on ambient temperature (Japanese Unexamined Patent Publication No. 2022-36766).

The thin film filter is inserted into the optical path of the light to be measured, as necessary. When the thin film filter is inserted to the light path, the transmittance of the thin film should be taken into account in measured values. Manufacturers of measurement apparatuses measure the transmittance of the thin film filter in calibration (factory calibration) and store the measured transmittance as a correction factor in the optical measurement apparatus. The measurement values are appropriately corrected to retain linear continuity of the measurement values before and after the thin film filter is inserted to the optical path.

It is known that the transmittance of a thin film filter has polarization dependence depending on the incident angle of light to be measured. Theoretically, there is no polarization dependence at vertical incidence. However, latest investigations found out that a thin film filter has a minute level of polarization dependence at vertical incidence.

Such a minute level of polarization dependence has been considered to be within a range of a measurement error in many optical measurement apparatuses and has not been noticed or regarded as a problem. However, such a minute level of polarization dependence can cause unignorable errors in measurement results of a high-precision optical measurement apparatus because the actual transmittance differs from the stored correction factor of the filter.

An object of the present invention is to provide: an optical filter and an optical filter unit capable of performing optical measurement with higher accuracy; a method of manufacturing the optical filter and the optical filter unit; and an optical measurement apparatus capable of reducing measurement errors that depend on the polarization direction of light to be measured.

### SUMMARY OF THE INVENTION

To achieve at least one of the abovementioned objects, according to an aspect of the present invention, there is provided an optical filter having a light transmittance characteristic or a light reflectance characteristic for a predetermined wavelength range, the optical filter including: a first optical function layer and a second optical function layer each having a transmittance that varies in a polarization direction of linearly polarized light at vertical incidence, wherein: the first optical function layer and the second optical function layer each have a high transmittance axis, the high transmittance axis being determined by a polarization direction in which transmittance of linearly polarized light at vertical incidence is greatest, and the first optical function layer and the second optical function layer are disposed such that an angle formed by the high transmittance axis of the first optical function layer and the high transmittance axis of the second optical function layer is within a range of 90°±30°.

### BRIEF DESCRIPTION OF THE DRAWINGS

The advantages and features provided by one or more embodiments of the invention will become more fully understood from the detailed description given hereinafter and the appended drawings which are given by way of illustration only, and thus are not intended as a definition of the limits of the present invention, and wherein:

FIG. 1 is a block diagram illustrating an example of the configuration of a tristimulus value-type optical measurement apparatus 10 of the present embodiment;

FIG. 2 is a diagram illustrating a method of measuring polarization dependence of transmittance of vertically incident light;

FIG. 3 is a graph illustrating actually measured polarization dependence of transmittance of vertically incident light of a filter having the average transmittance of about 4.7% as an example;

FIG. 4 is a graph illustrating actually measured polarization dependence of transmittance of vertically incident light of the filter having the average transmittance of about 4.7% as an example;

FIG. 5 is a schematic cross-sectional view of an example of a filter 40 of the present embodiment;

FIG. 6 is a schematic cross-sectional view of an example of the filter 40 of the present embodiment;

FIG. 7 is a perspective view of a filter 50 for measurement at the rotation angle of 0° when the polarization dependence of transmittance is measured;

FIG. 8 is a perspective view of the filter 50 with the rotation angle of 45° when the polarization dependence of transmittance is measured;

FIG. 9 is a perspective view of the filter 50 at the rotation angle of 90° when the polarization dependence of transmittance is measured;

FIG. 10 is a graph illustrating an example of an optical function layer having transmittance that varies in a polarization direction of linearly-polarized light at vertical incidence;

FIG. 11 is a diagram illustrating the relation between a first high transmittance axis 61 and a second high transmittance axis 62 of the filter 40 of the present embodiment;

FIG. 12 is a graph illustrating the fluctuation rate of the transmittance of the filter when the amplitude A1=A2=1.0% and the angle α=0°;

FIG. 13 is a graph illustrating the fluctuation rate of the transmittance of the filter when the amplitude A1=A2=1.0% and the angle α=90°;

FIG. 14 is a graph of the fluctuation rate of the transmittance of the filter when the amplitude A1=1.0%, A2=0.5% and the angle α=90°;

FIG. 15 is a graph illustrating the fluctuation rate of the transmittance of the filter when the amplitude A1=A2=1.0% and the angle α=105°;

FIG. 16 is a graph illustrating the fluctuation rate of the transmittance of the filter when the amplitude A1=A2=1.0% and the angle α=120°;

FIG. 17 is a schematic cross-sectional view of a measurement apparatus 70 that is used to determine the high reflectance axis of the optical function layer of the filter 40;

FIG. 18 is a schematic cross-sectional view of an example of a filter unit 44 according to the present embodiment;

FIG. 19 is a diagram illustrating the relation between a third high transmittance axis 63 and a fourth high transmittance axis 64 of the filter unit 44 according to the present embodiment;

FIG. 20 is a schematic cross-sectional view of a drum-type film forming apparatus 80 utilizing the radical assisted sputtering (RAS) method as viewed from above;

FIG. 21 is a flowchart of manufacturing methods (1) and (2);

FIG. 22 illustrates a substrate 41 held by the drum 81 in the first layer formation step S1 as viewed from the target facing the substrate 41;

FIG. 23 illustrates the substrate 41 held by the drum 81 after the rotation step S2 as viewed from the target facing the substrate 41;

FIG. 24 is a schematic cross-sectional view of an example of a filter 92 manufactured by the manufacturing method (3);

FIG. 25 illustrates the substrate 41 held by the drum 81 in the third layer formation step S1 as viewed from the target facing the substrate 41;

FIG. 26 is a flow of the steps of the production method (4);

FIG. 27 is a graph illustrating the relation between the rotation angle of a filter (a) and the fluctuation rate of reflectance; and

FIG. 28 is a graph illustrating the relation between the rotation angle of a filter (b) and the fluctuation rate of reflectance.

### DETAILED DESCRIPTION

Hereinafter, one or more embodiments of the present invention will be described with reference to the drawings. However, the scope of the invention is not limited to the disclosed embodiments.

### [Configuration of Optical Measurement Apparatus]

The optical measurement apparatus according to the present embodiment includes an optical filter or an optical filter unit, which will be described later. The optical measurement apparatus may be any apparatus that measures physical quantities using light. In the present embodiment, a photometric apparatus will be described. A photometric apparatus measures the intensity of light (e.g., brightness or chromaticity) emitted by a measurement target.

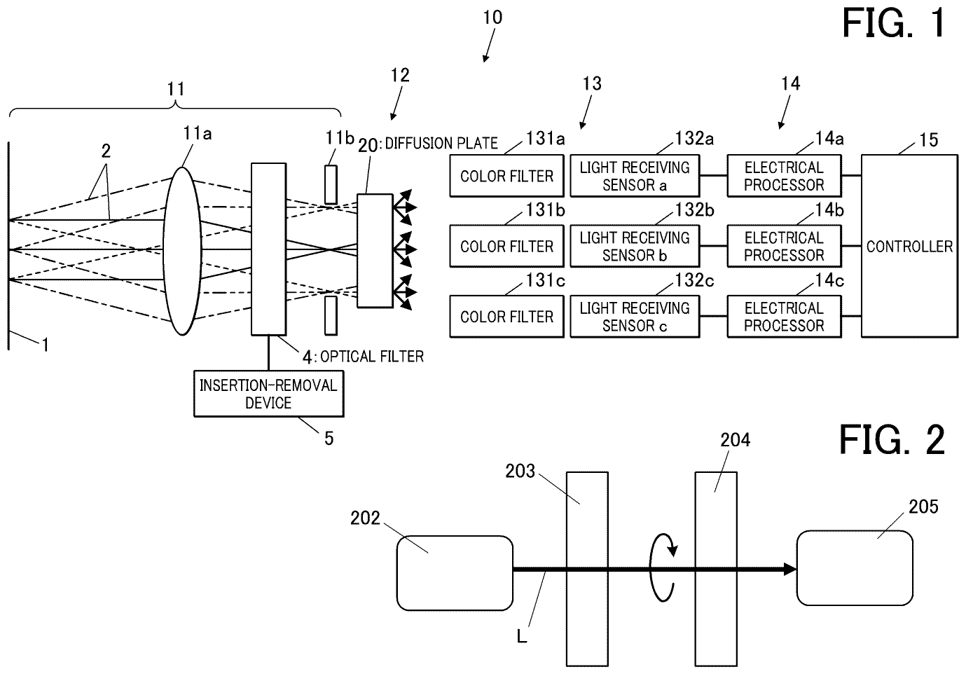

FIG. 1 is a block diagram illustrating an example of the configuration of a tristimulus value-type optical measurement apparatus 10 of the present embodiment. The optical measurement apparatus 10 in FIG. 1 is a photometric apparatus and measures brightness or chromaticity of a measurement target 1. The optical measurement apparatus 10 is used, for example, in the inspection process of manufacturing lines for manufacturing smartphone displays, and measures brightness, chromaticity, and so forth of display surfaces.

The optical measurement apparatus 10 includes an object optical system 11, a splitting optical system 12, a colorimetric optical system 13, an electrical processor 14, and a controller 15 (hardware processor).

The object optical system 11 includes a convex lens 11a having positive power, an optical filter 4, and an aperture diaphragm 11b. The splitting optical system 12 includes a diffusion plate 20 that splits and diffuses light.

The aperture diaphragm 11b is disposed at the focal position behind the convex lens 11a. The front-side telecentric optical arrangement can capture components within ±2.5 degrees to the normal of the surface to be measured, which is the display surface of the measurement target 1. The diffusion plate 20 is disposed at a position behind the aperture diaphragm 11b. The optical filter 4 is disposed between the convex lens 11a and the diffusion plate 20 and in front of the aperture diaphragm 11b.

The optical filter 4 is driven by the insertion-removal device 5. The insertion-removal device 5 inserts the optical filter 4 into the optical path of the light 2 to be measured or removes the optical filter 4 from the optical path. The insertion-removal device 5 is a linear actuator, for example. In the state where the optical filter 4 is inserted in the light path of the light 2, the intensity of the light 2 incident on the diffusion plate 20 is reduced by the optical filter 4. In the state where the optical filter 4 is removed from the optical path of the light 2, the light 2 enters the diffusion plate 20 without decreasing its intensity. The optical filter 4 is also referred to as a “neutral density (ND) filter”.

The optical filter 4 is inserted or removed depending on the brightness of the measurement target 1. When the measurement target 1 is dark, the optical filter 4 is removed from the optical path. When the measurement target 1 is bright, the optical filter 4 is inserted in the optical path to reduce the intensity of light, thereby preventing saturation of the light receiving sensors 132a, 132b, and 132c. The intensity of the light 2 is thus regulated within the dynamic range of the light receiving sensors 132a, 132b, and 132c, so that the dynamic range of the optical measurement apparatus 10 is expanded.

It is important that the optical filter 4 has spectral flatness (uniformity) and that the transmittance does not change depending on the ambient temperature. This is because the flatness of the optical filter 4 affects the spectral responsivity in the insertion and removal state of the optical filter 4 (presence or absence of the optical filter 4). If the optical filter 4 does not have spectral flatness, the light reception spectral sensitivity changes depending on whether the optical filter 4 is inserted. When the light reception spectral sensitivity deviates from the color matching function, errors occur in brightness and chromaticity.

A glass absorption filter is inferior in spectral flatness, and its transmittance greatly varies depending on environment temperature. Further, the glass absorption filter has a relatively low degree of freedom in designing a transmission spectrum. A perforated plate has spectral flatness but may not measure light-receiving angles evenly. Further, strict position reproducibility is required for the perforated plate.

On the other hand, a thin film filter has spectral flatness, and its transmittance does not change greatly depending on environment temperature. A thin film filter is therefore preferable as the optical filter 4. A thin film filter has a relatively high degree of freedom in designing a transmission spectrum, and its transmittance does not change greatly depending on environment temperature and environment humidity. The thin film layer therefore has a relatively high level of stability.

The colorimetric optical system 13 includes color filters 131a, 131b, 131c; and light receiving sensors 132a, 132b, 132c. The color filters 131a, 131b, and 131c are wavelength filters and are color matching function filters corresponding to three stimulation values of X, Y, and Z, respectively. The light receiving sensors 132a, 132b, and 132c are light receiving elements used in combination with the color matching function filters.

The color filters 131a, 131b, and 131c may be constituted of layers of light absorption-type filters to have transmittance corresponding to desired spectral characteristics, such as the three stimulus values of X, Y, and Z. However, such a structure may not allow designing a filter having transmittance peaks in two wavelength ranges. That is, such a structure has a low degree of freedom in designing a filter. In addition, a light absorption-type filter has a low degree of transmittance and has a great loss of light intensity. Furthermore, a film-like color filter is not stable because it greatly deteriorates over time by heat, light (ultraviolet rays), and humidity.

It is therefore preferable that the color filters 131a, 131b, and 131c be interference film filters. An interference film filter is formed by layering dozens of layers of dielectrics, oxides, and other materials on a glass substrate by vacuum evaporation, sputtering, or other methods. The interference film filter selects a wavelength to transmit or reflect by the interference effect of light.

With the interference film filter, a desired transmittance is more easily obtained (i.e., transmittance is more easily designed) than a light absorption-type filter. The interference film filter has a higher degree of freedom in design. The interference film filter also allows production of a filter having two peaks (mountains), such as the color matching function X. The interference film filter also has high transmittance. For example, the interference film filter has the peak transmittance close to 100%, whereas the light absorption type filter has the peak transmittance of 50% or less. Furthermore, the transmittance of the interference film filter does not change greatly over time by the exposure to temperature, humidity, and light.

As the light receiving sensors 132a, 132b, and 132c, silicon sensors are used, for example. The light received by the light receiving sensors 132a, 132b, and 132c is converted into an electric signal, and is subjected to processing, such as I/V conversion processing and amplification processing, by the corresponding electric processors 14a, 14b, and 14c. The processed electrical signal is input to the controller 15 as numerical data. Based on the input numerical data, the controller 15 calculates a measured value.

When the optical filter 4 is inserted in the optical path, correction of measurement values is performed in calculating the measurement values. In the correction, calculations are performed using a correction factor held by the controller 15. The correction factor is determined in factory calibration at a manufacturer of measurement apparatuses, for example. Specifically, the correction factor is determined as follows: the measured value with the optical filter 4 on the optical path and the measured value without the optical filter 4 on the optical path are obtained by using a reference light source; and the correction factor is determined such that these measured values are equal.

FIG. 2 illustrates the method of measuring the minute polarization dependence of the transmittance of the thin film filter (the optical filter 4) with respect to vertically incident light. The light L from the light source 202 (e.g., an LED, a laser, a lamp) is passed through the polarizing plate 203 and is turned into linearly polarized light having a fixed polarization direction. The linearly polarized light is vertically incident on the thin film filter 204, and light at about 0° is measured by the light receiver 205. By measuring the transmittance of the rotated thin film filter 204, the polarization dependence of transmittance with respect to vertically incident light can be measured.

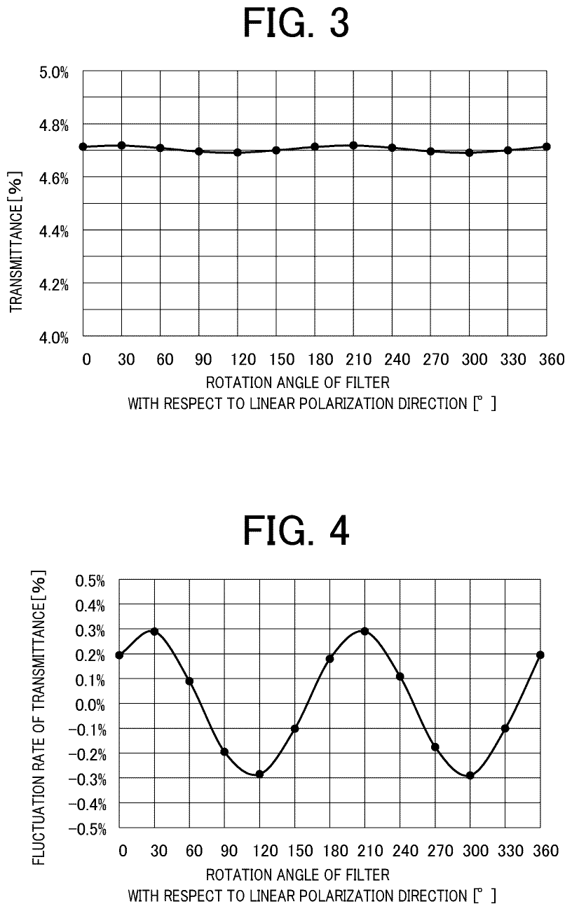

FIG. 3 and FIG. 4 show actually measured polarization dependence of transmittance of vertically incident light of the thin film filter having the average transmittance of about 4.7% as an example. In the graphs of FIG. 3 and FIG. 4, the horizontal axis indicates the rotation angle [°] of the filter with respect to the linear polarization direction. In the graph of FIG. 3, the vertical axis indicates transmittance [%]. In the graph of FIG. 4, the vertical axis indicates the fluctuation rate [%] of transmittance.

As shown in FIG. 3, the transmittance of the thin film filter slightly varies within the range of 4.686% to 4.714%, depending on the polarization direction. FIG. 4 is a graph focusing on these minute variations. FIG. 4 shows that the transmittance of the thin film filter varies within the range of ±0.3%, depending on the polarization direction and that the thin film layer has a minute level of polarization dependence.

Since such a minute polarization dependence is within the range of a measurement error, it has not been noticed or regarded as a problem in many optical measurement apparatuses. However, such a minute level of polarization dependence can cause great errors in measurement results of a high-precision optical measurement apparatus because the stored correction factor of the filter differs from the actual transmittance.

Assume that, in the optical measurement apparatus 10, the transmittance of the thin film filter as the optical filter 4 has polarization dependence for vertically incident light. If the reference light source used in calibration includes a diffusion plate, the light emitted by the reference light source is randomly polarized light. In such a case, the correction factor is determined to be the average value of the polarization dependence of the transmittance of the optical filter 4. Thereafter, in a measurement by the optical measurement apparatus 10, when the light 2 to be measured is randomly polarized light or completely circularly polarized light, a measurement error does not occur with the determined correction factor. However, when the light 2 to be measured is linearly polarized light or elliptically polarized light, the optical filter 4 is influenced by polarization dependence, and the transmittance deviates from the transmittance in calibration. Accordingly, a measurement error occurs. When the measurement target 1 is a display of a smartphone or a liquid crystal monitor, the light emitted by the measurement target 1 is often linearly polarized light or elliptically polarized light.

When the measurement target 1 itself is used as the reference light source in calibration, the polarization direction of the light emitted by the reference light source in calibration is the same as the polarization direction of the light emitted by the light 2 to be measured. Therefore, no measurement error occurs. However, if the angle of the measurement target 1 is different in calibration and in measurement, the polarization direction of the light emitted by the reference light source in calibration does not match the polarization direction of the light 2 to be measured. Accordingly, a measurement error occurs. If calibration is performed and a correction factor is determined at each time of measurement, the position of the measurement target 1 is unchanged in calibration and in measurement. However, calibration is generally performed only in factories of measuring apparatus manufacturers. In view of the above, an optical filter or an optical filter unit that has a decreased level of polarization dependence of transmittance of vertically incident light is used as the optical filter 4 to reduce measurement errors and improve accuracy.

### [Configuration of Optical Filter]

The optical filter of the present embodiment has a light transmittance characteristic or a light reflectance characteristic with respect to a predetermined wavelength range. Hereinafter, an “optical filter” may be simply referred to as a “filter”. The filter of the present embodiment satisfies the following expression (2), where Tmin is the minimum value and Tmax is the maximum value of the intensity of transmitted light when the polarization direction of linearly polarized light at vertical incidence is changed.

$$( Tmin / Tmax ) \times 1 \; 00 [ \% ] \geq 95 [ \% ] \qquad Expression ( 2 )$$

That is, the filter of the present embodiment has almost no polarization function. Examples of the filter include a wavelength filter and a neutral density (ND) filter. Examples of the wavelength filter include a band-pass filter, a high-pass filter, a low-pass filter, a notch filter, and color matching function filters corresponding to three stimulus values of X, Y, and Z. For example, a polarizing filter (polarizing plate) that does not satisfy the above Expression (2) is not used as the filter of the present embodiment.

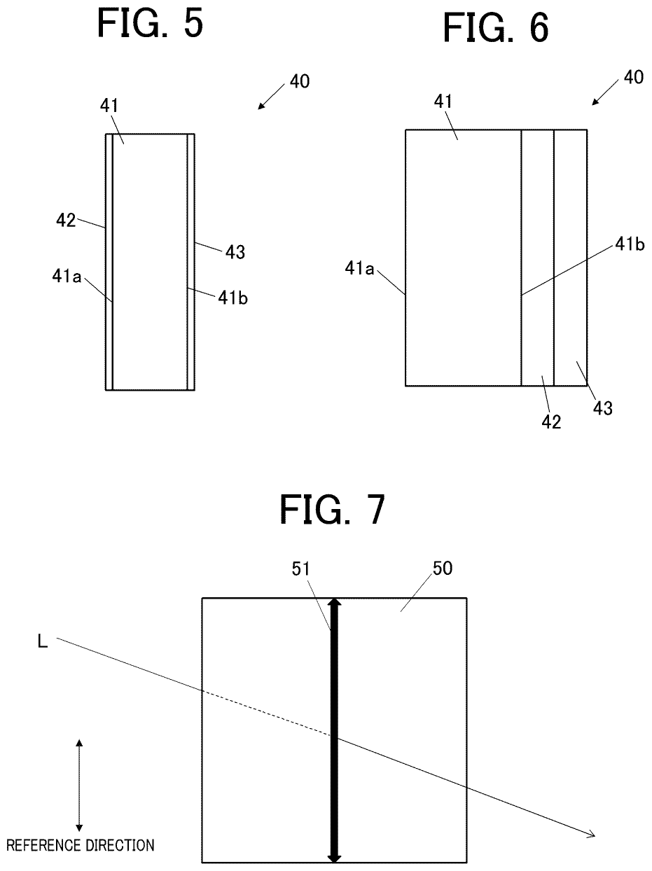

FIG. 5 is a schematic cross-sectional view of an example of a filter 40 of the present embodiment. As illustrated in FIG. 5, the filter 40 includes a first optical function layer 42, a second optical function layer 43, and a substrate 41 that supports these layers.

The first optical function layer 42 is disposed on one surface of the substrate 41, and the second optical function layer 43 is disposed on the other surface of the substrate 41. The optical function layers are disposed on two surfaces of the substrate 41 that have the largest area, that face each other, and that correspond to the light incident surface and the light emission surface. In FIG. 5, the first optical function layer 42 is disposed on the incident surface 41a, and the second optical function layer 43 is disposed on the emission surface 41b of the substrate 41, as an example. The surfaces on which the first and second optical function layer 42,43 are disposed may be the other way around.

FIG. 6 is a schematic cross-sectional view of an example of the filter 40 of the present embodiment. In FIG. 6, the first optical function layer 42 and the second optical function layer 43 are disposed in layers on the emission surface 41b of the substrate 41. Although the first optical function layer 42 and the second optical function layer 43 are layered on the emission surface 41b of the substrate 41 in FIG. 6, they may be layered on the incident surface 41a.

The first optical function layer 42 and the second optical function layer 43 may have the same film structure or different film structures.

The first optical function layer 42 and the second optical function layer 43 may be made of the same material or different materials. The first optical function layer 42 and the second optical function layer 43 may be, for example, an interfering film using a dielectric material, such as SiO2 and MgF2. The first optical function layer 42 and the second optical function layer 43 may be, for example, a metal-oxide film using a metal-oxide material, such as Al2O3, TiO2, Nb2O5, and NbO. The first optical function layer 42 and the second optical function layer 43 may be, for example, a film using a metal material, such as Cr and Nb.

The substrate 41 is made of a transparent optical material. The optical material can be appropriately selected according to the wavelength range of the light 2 to be measured. Examples of the optical material include glass, plastic, quartz crystal, and sapphire.

### [Polarization Dependence of Optical Function Layer]

In the present embodiment, the “high transmittance axis determined by a polarization direction in which linearly polarized light at perpendicular incidence is transmitted most” is determined by the following procedure.

The polarization dependence of transmittance of the optical function layer for vertically incident light is measured by the method illustrated in FIG. 2 described above. In the measurement, a measurement filter having a single optical function layer is used as a sample.

FIG. 7 is a perspective view of a filter 50 for measurement at the rotation angle of 0° when the polarization dependence of transmittance is measured. The linearly polarized light L that has passed through the polarizing plate 203 enters the measurement filter 50. Before the filter 50 is rotated (i.e., when the rotation angle of the filter 50 is 0°), the axis parallel to the reference direction is defined as a position 51 at the rotation angle of 0°.

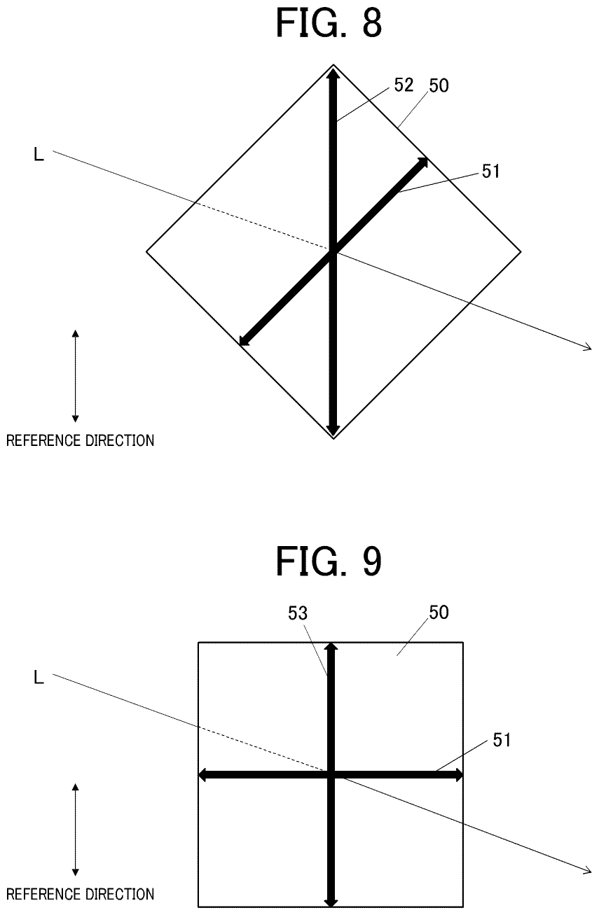

FIG. 8 is a perspective view of the filter 50 for measurement at the rotation angle of 45° when the polarization dependence of transmittance is measured. In FIG. 8, the filter 50 is rotated clockwise by 45° from the position of FIG. 7 on the center of the filter 50 as the rotation center. At the rotation angle of 45°, the axis parallel to the reference direction is defined as a position 52 at the rotation angle of 45°.

FIG. 9 is a perspective view of the filter 50 at the rotation angle of 90° when the polarization dependence of transmittance is measured. In FIG. 9, the measurement filter 50 is rotated clockwise by 90° from the position of FIG. 7 on the center of the measurement filter 50 as the rotation center. At the rotation angle of 90°, the axis parallel to the reference direction is defined as a position 53 at the rotation angle of 90°.

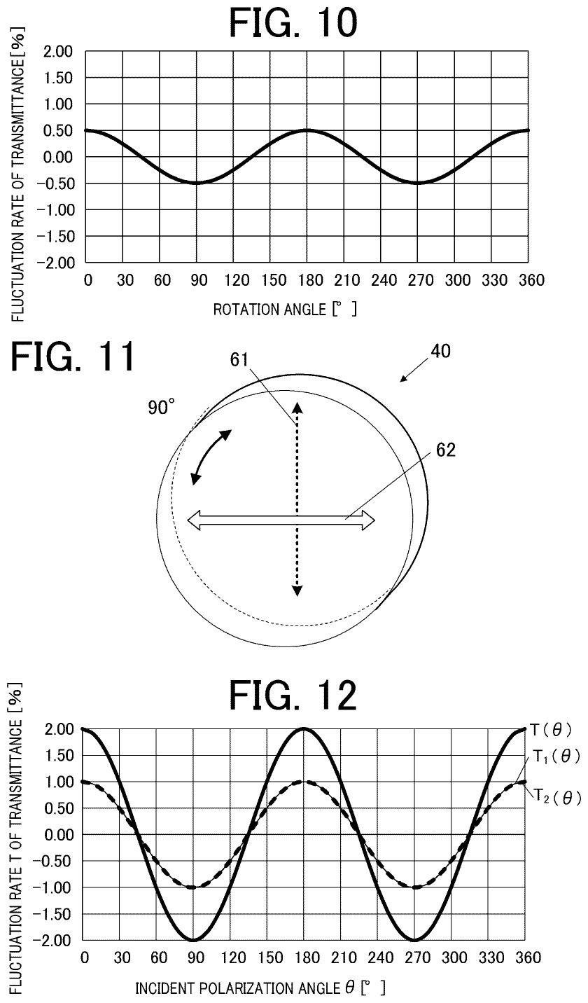

FIG. 10 is a graph illustrating an example of an optical function layer having transmittance that varies in a polarization direction of linearly polarized light at vertical incidence. The horizontal axis of the graph indicates the rotation angle [°] of the optical function layer (filter for measurement). The vertical axis indicates the fluctuation rate [%] of the transmittance of the optical function layer (filter for measurement). The fluctuation rate of the transmittance of the optical function layer can be calculated as the ratio with respect to the average transmittance as a reference value, as expressed by the following expression. As shown in FIG. 10, the relation between the rotation angle [°] of the optical function layer and the fluctuation rate [%] of the transmittance can be fitted to a sine curve.

$$Fluctuation rate of transmittance [ \% ] = \{ ( transmittance at specific rotation angle - average transmittance ) / average transmittance \} \times 100 \qquad Expression$$

In the example of FIG. 10, the amplitude of the sine curve of the fluctuation rate is 0.5%, and the transmittance changes by 1.0% at most. In the example of FIG. 10, the fluctuation rate is greatest (i.e., the transmittance is greatest) when the rotation angle is 0° and 180°. Therefore, the position of the optical function layer at the rotation angle of 0° and the position thereof at the rotation angle of 180° are defined as the “high transmittance axis determined by the polarization direction in which transmittance of linearly polarized light at vertical incidence is greatest”. Hereinafter, it is also simply referred to as “high transmittance axis”.

FIG. 11 is a diagram illustrating the relation between a first high transmittance axis 61 and a second high transmittance axis 62 of the filter 40 of the present embodiment. The first high transmittance axis 61 is the high transmittance axis of the first optical function layer 42. The second high transmittance axis 62 is the high transmittance axis of the second optical function layer 43. The first optical function layer 42 and the second optical function layer 43 are disposed such that the angle formed by the first high transmittance axis 61 and the second high transmittance axis 62 is within the range of 90°±30°. Thus, the polarization dependence of the filter 40 can be reduced. In FIG. 11, the angle of intersection is 90° as an example.

Following is the description of the relation between the angle at which the first high transmittance axis 61 and the second high transmittance axis 62 intersect and the transmittance of the filter. Herein, the fluctuation rate T of the transmittance is assumed to form a sine wave.

The fluctuation rate T1 (θ) of the transmittance of the first optical function layer 42 is expressed by the following expression (I).

$$T 1 ( θ ) = A 1 \times cos 2 θ \qquad Expression ( I )$$

The angle θ represents a polarization angle of the incident linearly-polarized light when the first high transmittance axis 61 is 0°. The amplitude A1 represents the difference between the maximum transmittance and the average transmittance.

The fluctuation rate T2 (θ) of the transmittance of the second optical function layer 43 is expressed by the following expression (II).

$$T 2 ( θ ) = A 2 \times cos 2 ( θ - α ) \qquad Expression ( II )$$

The angle θ represents a polarization angle of the incident linearly-polarized light when the first high transmittance axis 61 is 0°. The amplitude A2 represents the difference between the average transmittance and the maximum transmittance. The angle α represents an angle at which the first high transmittance axis 61 and the second high transmittance axis 62 intersect.

The fluctuation rate T (θ) of the transmittance of the filter including the first optical function layer 42 and the second optical function layer 43 is expressed by the following expression (III).

$$T ( θ ) = T 1 ( θ ) + T 2 ( θ ) \qquad Expression ( III )$$

FIG. 12 is a graph illustrating the fluctuation rate of the transmittance of the filter when the amplitude A1=A2=1.0% and the angle α=0°. The horizontal axis of the graph indicates the polarization angle θ [°] of the linearly polarized light incident on the filter. The vertical axis of the graph indicates the fluctuation rate T [%] of the transmittance of the filter. In the graph of FIGS. 12, T1 (θ) and T2 (θ) completely match each other.

At this time, as shown in FIG. 12, the amplitude of T (θ) is greater than the amplitudes of T1 (θ) and T2 (θ). That is, the polarization dependence increases by the combination of the first optical function layer 42 and the second optical function layer 43, and the fluctuation of the transmittance of the filter becomes greater than when the function layers 43, 43 are used separately.

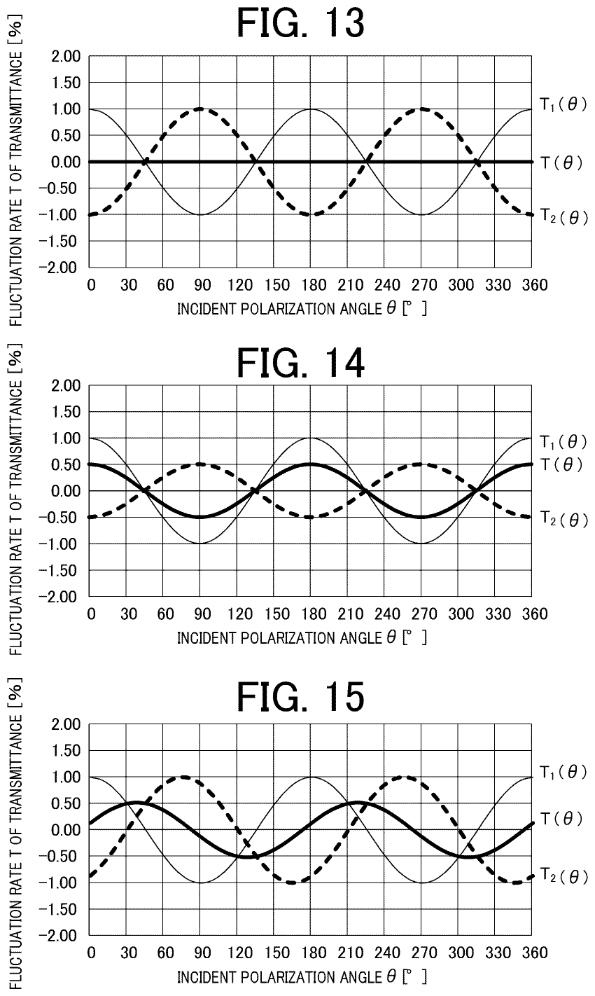

FIG. 13 is a graph illustrating the fluctuation rate of the transmittance of the filter when the amplitude A1=A2=1.0% and the angle α=90°. The horizontal axis of the graph indicates the polarization angle θ [°] of the linearly polarized light incident on the filter. The vertical axis of the graph indicates the fluctuation rate T [%] of the transmittance of the filter.

As shown in FIG. 13, T (θ) is a constant value. That is, by the combination of the first and second optical function layers 42, 43, the first and second optical function layers 42, 43 cancel each other's polarization dependence, so that the transmittance of the filter does not fluctuate.

FIG. 14 is a graph of the fluctuation rate of the transmittance of the filter when the amplitude A1=1.0%, A2=0.5%, and the angle α=90°. The amplitude A2 is ½ of the amplitude A1. The horizontal axis of the graph indicates the polarization angle θ [°] of the linearly polarized light incident on the filter. The vertical axis of the graph indicates the fluctuation rate T [%] of the transmittance of the filter.

As shown in FIG. 14, the amplitude of T (θ) is smaller than the amplitude of T1 (θ). That is, by using the first optical function layer 42 and the second optical function layer 43 in combination, the polarization dependence of the first optical function layer 42 is partially cancelled by the second optical function layer 43, and the fluctuation of the transmittance of the filter becomes ½ of the first optical function layer 42.

FIG. 15 is a graph illustrating the fluctuation rate of the transmittance of the filter when the amplitude A1=A2=1.0% and the angle α=105°. The horizontal axis of the graph indicates the polarization angle θ [°] of the linearly polarized light incident on the filter. The vertical axis of the graph indicates the fluctuation rate T [%] of the transmittance of the filter.

As shown in FIG. 15, the amplitude of T (θ) is smaller than the amplitudes of T1 (θ) and T2 (θ). That is, by using the first optical function layer 42 and the second optical function layer 43 in combination, the polarization dependence of the first optical function layer 42 is partially cancelled by the second optical function layer 43, and the fluctuation of the transmittance of the filter becomes ½ of the first optical function layer 42.

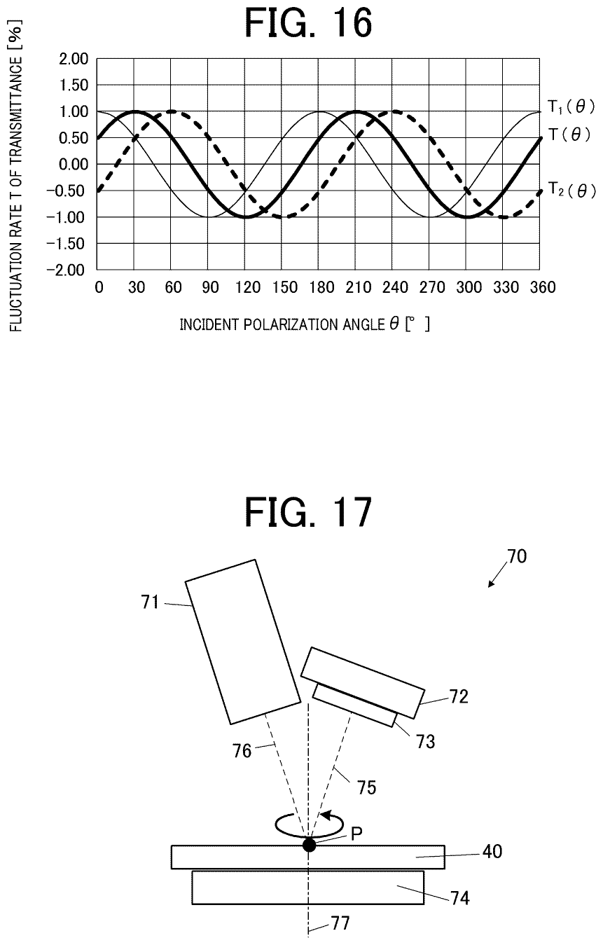

FIG. 16 is a graph illustrating the fluctuation rate of the transmittance of the filter when the amplitude A1=A2=1.0% and the angle α=120°. The horizontal axis of the graph indicates the polarization angle θ [°] of the linearly polarized light incident on the filter. The vertical axis of the graph indicates the fluctuation rate T [%] of the transmittance of the filter.

As shown in FIG. 16, the amplitude of T (θ) is equal to the amplitude of T1 (θ) and T2 (θ). That is, by using the first optical function layer 42 and the second optical function layer 43 in combination, the polarization characteristic of the first optical function layer 42 is partially cancelled by the second optical function layer 43, and the fluctuation of the transmittance of the filter becomes equal to that of the first optical function layer 42.

When the angle α is within the range of 90°±30°, the fluctuation of the transmittance of the filter can be made smaller than the fluctuation of the transmittance of the first optical function layer 42 only or the second optical function layer 43 only. It is preferable that the angle α be within the range of 90°±15° and more preferable that the angle α be 90°.

As described above, the relation between the rotation angle of the optical function layer and the fluctuation rate of the transmittance can be fitted to a sine curve. The amplitude A of the sine curve can be expressed as a difference between the maximum transmittance and the average transmittance of the optical function layer. When the layer having a greater difference between the maximum transmittance and the average transmittance is the first optical function layer 42 and the layer having a smaller difference is the second optical function layer 43, it is preferable that the following expression (1) be satisfied.

$$( T 2 max - T 2 ave ) / ( T 1 max - T 1 ave ) \geq 1 / 2 \qquad Expression ( 1 )$$

In the above expression, T1max and T1ave represent the maximum transmittance and the average transmittance of the first optical function layer, respectively; and T2max and T2ave represent the maximum transmittance and the average transmittance of the second optical function layer, respectively.

That is, it is preferable that the amplitude A2 be greater than ½ of the amplitude A1 when the amplitude A1 is greater than A2. Thus, the polarization dependence of the first optical function layer 42 is effectively cancelled by the second optical function layer 43, so that the fluctuation of the transmittance of the filter can be further reduced.

It is preferable that the amplitude A1 be equal to the amplitude A2 and that the angle α be 90°. Thus, the fluctuation of the transmittance of the filter can be eliminated.

The filter 40 may have three or more optical function layers as long as the optical function layers used in combination can cancel each other's polarization dependence of the transmittance. For example, in the configuration illustrated in FIG. 6, the first optical function layer 42 and the second optical function layer 43 may also be provided on the incident surface 41a, so that the filter 40 has four optical function layers.

### [Method of Detecting High Transmittance Axis of Optical Function Layer]

If the first optical function layer 42 and the second optical function layer 43 of the filter 40 cannot be separated, it is relatively difficult to detect the first high transmittance axis 61 and the second high transmittance axis 62, based on the measurement of the transmittance. If the filter 40 is configured as illustrated in FIG. 5 and both the first optical function layer 42 and the second optical function layer 43 are exposed, the following method may be used to determine the first high transmittance axis 61 and the second high transmittance axis 62.

It is known that the optical function layer formed by the method described below has polarization dependence for both light transmission and light reflection and that the phase of polarization dependence of transmission is substantially the same as that of reflection. That is, it is known that the direction of the high transmittance axis is substantially the same as the direction of the low reflectance axis and that the angle at which the high transmittance axis intersects with the high reflectance axis is substantially 90°. Therefore, an approximate angle at which the first high transmittance axis 61 intersects with the second high transmittance axis 62 can be determined by detecting the high reflectance axis of the first optical function layer 42 and the high reflectance axis of the second optical function layer 43. Herein, the “high reflectance axis” is determined in the same procedure as the high transmittance axis except that reflectance is measured instead of transmittance.

FIG. 17 is a schematic cross-sectional view of a measurement apparatus 70 that is used to determine the high reflectance axis of the optical function layer of the filter 40. The measurement device 70 includes an optical measuring instrument 71, a flat light source 72, a polarizing plate 73, and a rotary stage 74.

First, the filter 40 as the measurement target is placed on the rotary stage 74. The filter 40 is placed such that either the first optical function layer 42 or the second optical function layer 43 faces the optical measuring instrument 71. It is preferable to put a mark on the placed filter 40 corresponding to the direction of 0° of the rotary stage 74.

Next, diffused light is emitted by the flat light source 72. The flat light source 72 may be, for example, a surface light emitter using a light emitting diode (LED). The diffused light emitted by the flat light source 72 enters the polarizing plate 73. The light 75 emitted by the polarizing plate 73 is linearly polarized uniformly diffused light. The light 75 illuminates the filter 40. The polarization direction of the light 75 is the vertical direction to the paper surface of FIG. 17. The light 75 illuminates the filter 40 as S-polarized light.

The intensity of the reflected light 76 that is reflected on the surface of the filter 40 is measured by the optical measuring instrument 71. In the measurement, it is preferable that the positions of the components be adjusted such that the axis of the light 75 passes through the intersection point P at which the stage rotation axis 77 intersects with the surface of the filter 40. Thus, a measurement error by the measurement positions can be reduced. It is preferable that the optical measuring instrument 71 be capable of measuring the light intensity with high accuracy. Examples of the optical measuring instrument 71 include a power meter and a luminance meter.

The intensity of the reflected light 76 is measured while the rotary stage 74 is rotated, and the reflectance is calculated. The polarization dependence of the reflected light can be determined by observing the fluctuation rate of the reflectance with respect to the average reflectance. After the polarization dependence is determined, the filter 40 is inverted and placed on the rotary stage 74 such that the mark corresponds to the direction of 0° of the rotary stage 74. For the back surface of the filter 40, the polarization dependence of the reflected light is determined by the same procedure. The high reflectance axis is determined by the same procedure as the setting of the high transmittance axis, and the high reflectance axis is treated as an approximation of the high transmittance axis. Based on the angle at which the high reflectance axes intersect, the angle at which the high transmittance axes intersect is determined. In the method described herein, the reflectance at oblique incidence is measured. However, it is more desirable to measure the reflectance at vertical incidence by using a configuration of coaxial lighting with a beam splitter, for example.

### [Configuration of Filter Unit]

The optical filter unit of the present embodiment includes a first optical filter and a second optical filter having light transmittance characteristics or light reflectance characteristics with respect to a predetermined wavelength range.

That is, as the filter unit of the present embodiment, an optical filter unit having almost no polarization function is used. Examples of the filter unit include a wavelength filter unit and a neutral density (ND) filter unit.

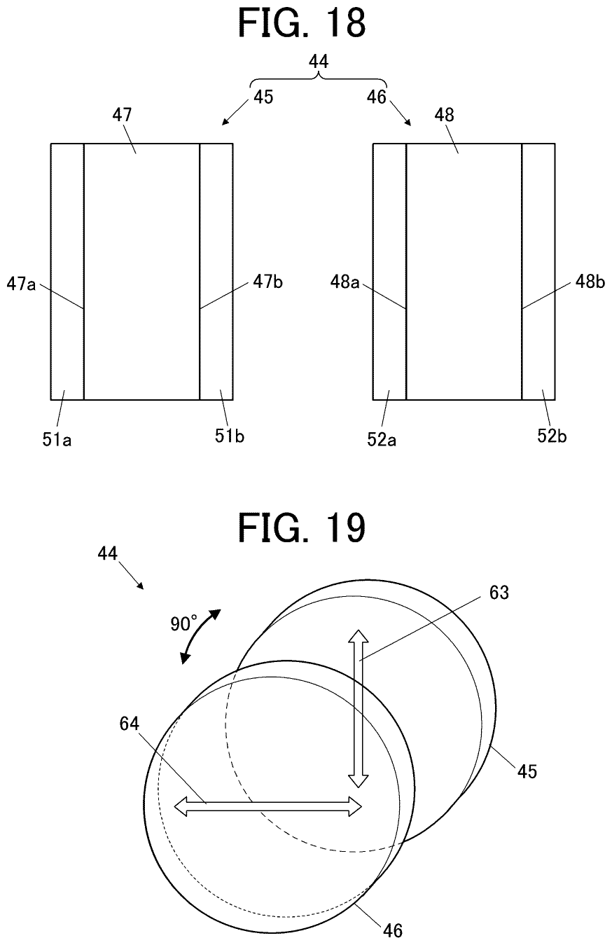

FIG. 18 is a schematic cross-sectional view of an example of a filter unit 44 according to the present embodiment. As illustrated in FIG. 18, the filter unit 44 includes a first filter 45 and a second filter 46. The first filter 45 includes third optical function layers 51a, 51b and a first substrate 47 that supports the third optical function layers 51a, 51b. The second filter 46 includes fourth optical function layers 52a, 52b and a second substrate 48 that supports the fourth optical function layers 52a, 52b.

In FIG. 18, the first filter 45 has two layers: the third optical function layers 51a, 51b. The third optical function layer may have a single layer or three or more layers. The third optical function layers 51a, 51b are provided on the incident surface 47a and the emission surface 47b of the first substrate 47, respectively. The third optical function layers 51a, 51b may be provided on either the incident surface 47a or the emission surface 47b only. Similarly, although the second filter 46 have two layers: the fourth optical function layers 52a and 52b, the fourth optical function layer may have a single layer or three or more layers. Although the fourth optical function layers 52a, 52b are provided on the incident surface 48a and the emission surface 48b of the second substrate 48, respectively, they may be provided on either the incident surface 48a or the emission surface 48b only.

FIG. 19 is a diagram illustrating the relation between a third high transmittance axis 63 and a fourth high transmittance axis 64 in the filter unit 44 according to the present embodiment. The third high transmittance axis 63 is the high transmittance axis of the first filter 45 and is the high transmittance axis of the entire third optical function layers 51a, 51b. The fourth high transmittance axis 64 is a high transmittance axis of the second filter 46 and is the high transmittance axis of the entire fourth optical function layers 52a, 52b. The first optical filter 45 and the second optical filter 46 are disposed such that the angle formed by the third high transmittance axis 63 and the fourth high transmittance axis 64 is within the range of 90°±30°. Thus, the polarization dependence of the filter unit 44 can be reduced. In FIG. 19, the angle of intersection is 90° as an example.

The filter unit 44 is to be designed in consideration of combining multiple filters. For example, to constitute an ND filter unit having a transmittance of 4%, the first filter 45 and the second filter 46 each have a transmittance of 20%. Since the transmittance varies depending on the front surface reflection, the back surface reflection, or the interplanar reflection, these influences are taken into consideration.

The filter unit 44 may have three or more filters as long as the combined filters can cancel each other's polarization dependence of transmittance.

### [Method of Manufacturing Filter and Filter Unit]

The method of manufacturing a filter according to the present embodiment is not limited to a specific method. Following is the description of a radical assisted sputtering (RAS) method using a drum type film forming apparatus. The RAS method repeats (i) a process of forming a metal film or a film of incomplete oxide of metal and (ii) a process of complete oxidation with an oxygen radical source. By the RAS method, a high-density oxide film can be quickly formed at low temperature. Following is the description of a film forming method using a general RAS drum type film forming apparatus.

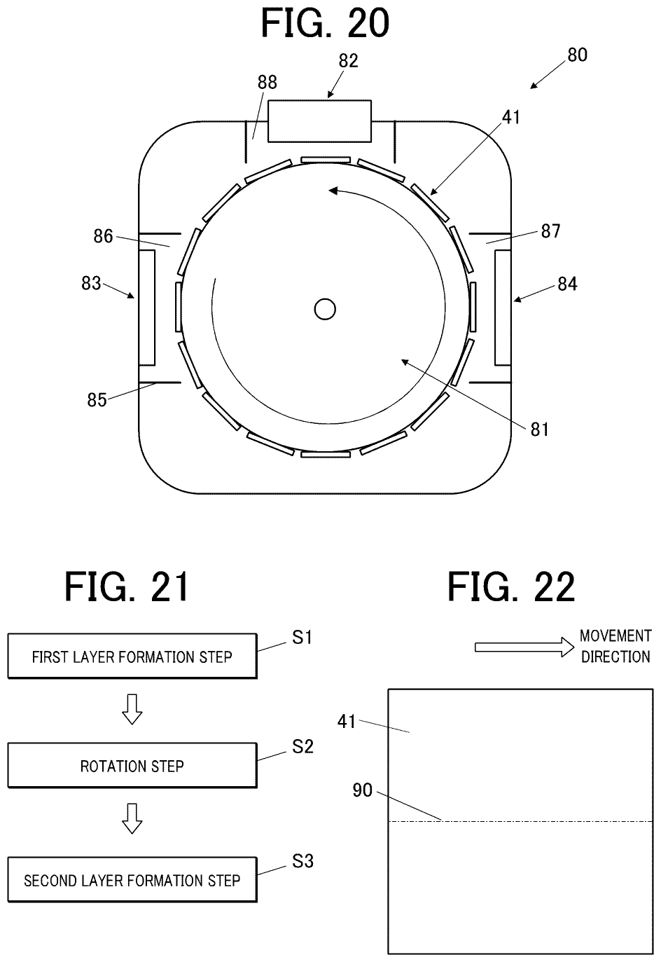

FIG. 20 is a schematic cross-sectional view of a drum-type film forming apparatus in the RAS method viewed from above. The film forming apparatus 80 includes a drum 81, a radical source 82, a first target 83, and a second target 84. The region in the film forming apparatus 80 may be partitioned by walls 85. The region near the first target 83 partitioned by the walls 85 is defined as a first region 86. The region near the second target 84 partitioned by the walls 85 is defined as a second region 87. The region near the radical source 82 partitioned by the walls 85 is defined as a third region 88. At the first target 83 and the second target 84, the material of the optical function layer is disposed.

The drum 81 rotates in the direction of the arrow in FIG. 20 while holding multiple substrates 41. Each of the substrates 41 is conveyed to the first region 86. In the first region, an argon gas is supplied, for example; the first target 83 is sputtered; and the first target 83 is deposited on the substrate 41. The substrate 41 is conveyed to the second region 87 by the rotating drum 81. In the second region, for example, an argon gas is supplied; the second target 84 is sputtered; and the second target 84 is deposited on the substrate 41, as in the first region. Sputtering may be performed only in the first region 86 to deposit only the first target 83 on the substrate 41.

Thereafter, the substrate 41 is conveyed to the third region 88 by the rotating drum 81. In the third region, argon gas, oxygen gas, nitrogen gas, or the like is supplied as needed, for example. When plasma is in contact with the film on the substrate 41, an oxidation reaction or a nitridation reaction proceeds, so that oxide or nitride of the target is deposited on the substrate 41.

As described above, the filter prepared by the above film forming method has the polarization dependence of transmittance for vertical incident light. This is considered to be due to the fact that during film formation, the substrate 41 is moved only in a specific direction by the rotating drum 81 and that the formed film has directionality. To deal with this, two films are disposed so as to cancel each other's directionality as described above. Such a configuration can reduce the polarization dependence of transmittance of the filter for vertically incident light. Further, it is considered that the polarization dependence of transmittance of the filter for vertically incident light can be reduced by avoiding moving the substrate 41 only in a specific direction during film formation.

Next, the following methods of manufacturing a filter or a filter unit are described in order.
(1) Method of manufacturing the filter 40 having the structure illustrated in FIG. 5
(2) Method of manufacturing the filter 40 having the structure illustrated in FIG. 6
(3) Method of manufacturing a filter 92 including only one fifth optical function layer 93 on a substrate 41
(4) Method of manufacturing a filter unit 44 having the structure illustrated in FIG. 18

### (1) Method of Manufacturing the Filter 40 Having the Structure Illustrated in FIG. 5

FIG. 21 is a flowchart of manufacturing methods (1) and (2). The manufacturing method (1) includes a first layer formation step S1, a rotation step S2, and a second layer formation step S3.

In the first layer formation step S1, the first optical function layer 42 is formed on the surface of the substrate 41 that moves in a specific direction with respect to a target. The target is a material of the first optical function layer 42.

FIG. 22 illustrates the substrate 41 held by the drum 81 in the first layer formation step S1 as viewed from the target facing the substrate 41. The straight arrow in FIG. 22 indicates the movement direction of the substrate 41 by the rotation of the drum 81. At this time, a mark 90 indicating the movement direction is put on the substrate 41. The first optical function layer 42 is formed on the surface of the substrate 41.

In the rotation step S2, the substrate 41 is inverted such that the back surface of the substrate 41 faces the target as the material of the second optical function layer 43. In the inversion, the substrate 41 is rotated in a specific direction on the center of the substrate 41 (the rotation center 91) within the range of 90°±30°.

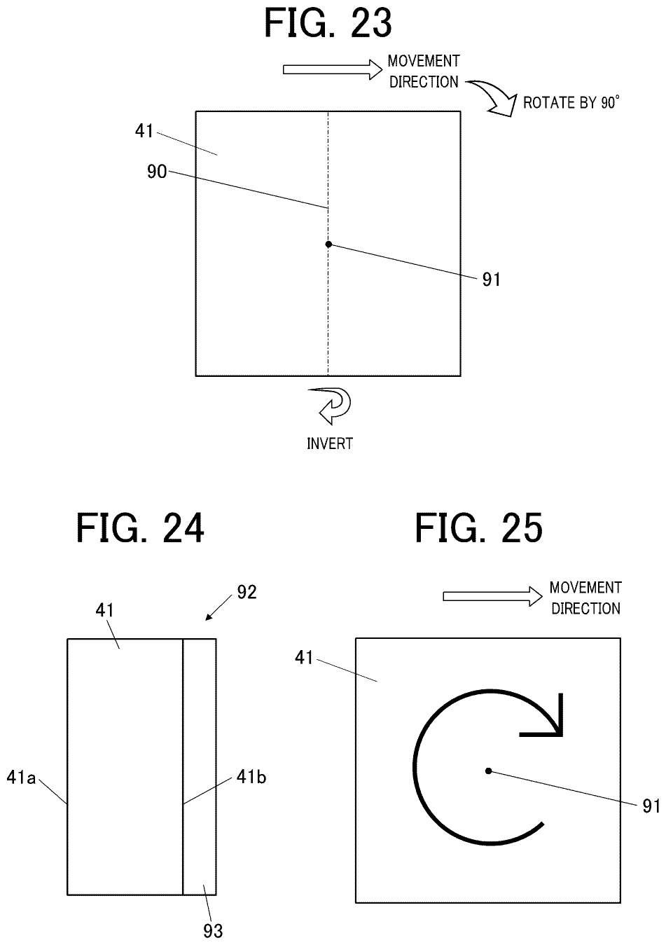

FIG. 23 illustrates the substrate 41 held by the drum 81 after the rotation step S2 as viewed from the target facing the substrate 41. The straight arrow in FIG. 23 indicates the movement direction of the substrate 41 by the rotation of the drum 81. In the rotation step S2, first, the substrate 41 is inverted such that the back surface of the substrate 41 faces the target. The substrate 41 is then rotated in the movement direction within the range of 90°±30° on the center of the substrate 41 (the rotation center 91). In FIG. 23, the substrate 41 is rotated by 90° as an example.

The direction of the high transmittance axis 61 of the first optical function layer 42, which is formed in the first layer formation step, may vary depending on the layer (film) formation conditions, the way the substrate 41 is attached, and so forth. Specifically, the direction of the high transmittance axis 61 may deviate from the rotation direction of the drum 81 by about ±20°. When such a deviation occurs, the high transmittance axis 61 and the high transmittance axis 62 do not intersect at 90° even when the substrate 41 is rotated by 90°, for example. To deal with this, the rotation angle may be appropriately adjusted in the rotation step S2. By adjusting the rotation angle, the first high transmittance axis 61 and the second high transmittance axis 62 can intersect at a desired angle in the manufactured filter 40. Specifically, first, the transmittance or the reflectance is measured by the above-described method; and the high transmittance axis 61 of the first optical function layer 42 formed in the first layer formation step is determined (high transmittance axis determination step). Next, based on the relation between the high transmittance axis 61 and the rotation direction of the drum 81, the rotation angle of the substrate 41 after inversion is calculated (rotation angle calculation step). The substrate 41 is inverted and rotated by the calculated angle (rotation step S2).

In the second layer formation step S3, the second optical function layer 43 is formed on the back surface of the substrate 41. Thus, the filter 40 including the first optical function layer 42 on the front surface of the substrate 41 and the second optical function layer 43 on the back surface thereof can be produced.

### (2) Method of Manufacturing the Filter 40 Having the Structure Illustrated in FIG. 6

The manufacturing method (2) includes the first layer formation step S1, the rotation step S2, and the second layer formation step S3.

In the first layer formation step S1, as in the first layer formation step S1 of the manufacturing method (1), the first optical function layer 42 is formed on the surface of the substrate 41 that moves in a specific direction with respect to a target. The target is the material of the first optical function layer 42.

In the rotation step S2, the substrate 41 is rotated in a specific direction on the center of the substrate 41 (the rotation center 91) within the range of 90°±30°. Unlike the rotation step S2 of the manufacturing method (1), the substrate 41 is not inverted in the rotation step S2 of the manufacturing method (2). Except that the substrate 41 is not inverted, the rotation step S2 of the manufacturing method (2) is the same as the rotation step S2 of the manufacturing method (1). The rotation angle may be appropriately adjusted, as described above.

In the second layer formation step S3, the second optical function layer 43 is formed on the first optical function layer 42. Thus, the filter 40 including the first optical function layer 42 and the second optical function layer 43 layered on one surface of the substrate 41 can be manufactured.

### (3) Method of Manufacturing a Filter Including Only a Fifth Optical Function Layer 93 on a Substrate 41

FIG. 24 is a schematic cross-sectional view of an example of a filter 92 manufactured by the manufacturing method (3). Although the filter 92 manufactured by the manufacturing method (3) does not correspond to the filter 40 having the above-described structure, the filter 92 can reduce the polarization dependence of the transmittance for vertically incident light. The filter 92 includes a fifth optical function layer 93 on either the incident surface 41a or the emission surface 41b of the substrate 41.

The manufacturing method (3) includes a third layer formation step. In the third layer formation step, the fifth optical function layer 93 is formed on the surface of the substrate 41 while the substrate 41 is moving in a specific direction with respect to a target and rotating in the specific direction on the center of the substrate 41 (the rotation center 91). The target is a material of the fifth optical function layer 93.

FIG. 25 illustrates the substrate 41 held by the drum 81 in the third layer formation step S1 as viewed from the target facing the substrate 41. The straight arrow in FIG. 25 indicates the movement direction of the substrate 41 by the rotation of the drum 81. The circular arrow in FIG. 25 indicates the rotation direction of the substrate 41. In the third layering process, the fifth optical function layer 93 is formed on the surface of the substrate 41 while the substrate 41 is rotated on the center of the substrate 41 (the rotation center 91) at a constant speed in the movement direction. That is, the substrate 41 is rotated in the direction of the circular arrow while moving in the direction of the straight arrow. Since the formed fifth optical function layer 93 does not have a high transmittance axis, the polarization dependence of the transmittance for vertically incident light can be reduced with a single layer.

### (4) Method of Manufacturing a Filter Unit 44 Having the Structure Illustrated in FIG. 18

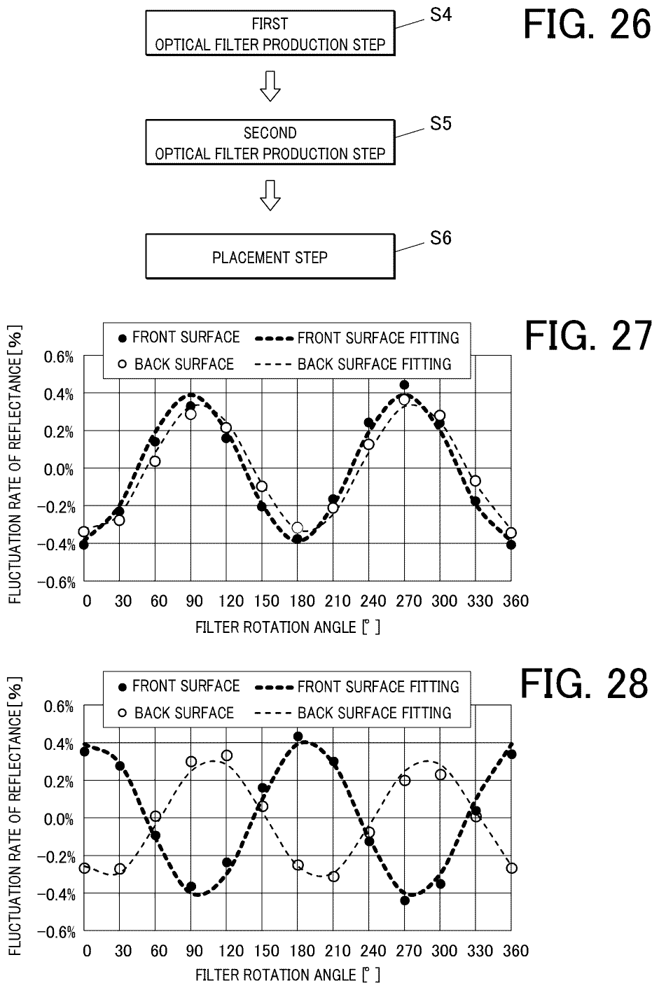

FIG. 26 is a flow of the steps of the production method (4). The manufacturing method (4) includes a first optical filter production step S4, a second optical filter production step S5, and a placement step S6.

In the first optical filter production step S4, the first filter 45 is produced by forming the third optical function layers 51a, 51b on the surfaces of the first substrate 47 that is moving in a specific direction with respect to a target. The target is a material of the first optical function layer 42.

In the second optical filter production step S5, the second filter 46 is produced by forming the fourth optical function layers 52a, 52b on the surfaces of the second substrate 48 that is moving in a specific direction with respect to a target. The target is a material of the second optical function layer 43.

In the first optical filter production step S4 and the second optical filter production step S5, a mark indicating the movement direction is put on the first substrate 47 and the second substrate 48, as in the first layer formation step S1 of the manufacturing method (1).

In the placement step S6, the first filter 45 and the second filter 46 are placed such that the angle formed by the mark indicating the movement direction of the first substrate 47 and the mark indicating the movement direction of the second substrate 48 is within the range of 90°±30°. Thus, the filter unit 44 including the first filter 45 having the first optical function layer 42 and the second filter 46 having the second optical function layer 43 can be manufactured. It is preferable that the first filter 45 and the second filter 46 be produced in the same batch to cancel the polarization dependence more effectively. For another example, transmittance or reflectance may be measured by the above-described method; the high transmittance axis 63 of the first filter 45 and the high transmittance axis 64 of the second filter 46 may be determined; and the first and second filters 45, 46 may be arranged such that the high transmittance axis 63 and the high transmittance axis 64 intersect at a desired angle.

It is considered that a film has directionality when formed by a sputtering method or a vacuum vapor deposition method other than the RAS method, when these methods use an apparatus for moving or rotating a substrate in a specific direction during film formation. Therefore, the present embodiment can also be applied to these methods.

### EXAMPLES

A filter (a) as a comparative example and a filter (b) having the structure illustrated in FIG. 5 were prepared. The filters (a) and (b) both have the first optical function layer 42 on the incident surface 41a of the substrate 41 and the second optical function layer 43 on the emission surface 41b of the substrate 41. The first optical function layer 42 and the second optical function layer 43 had the same structure. The filter (a) was prepared by the same procedure as the above-described manufacturing method (1) except that the substrate 41 was inverted but not rotated in the rotation step S2. The filter (b) was prepared by the above-described manufacturing method (1). In the rotation step S2 of the filter (b), the substrate 41 was inverted and then rotated on the center of the substrate 41 (the rotation center 91) by 90° in the movement direction.

### (Observation of Polarization Dependence of Filter)

The polarization dependence of the transmittance for vertical incident light of the filters (a) and (b) was measured by the above-described procedure. For the filter (a), the transmittance fluctuated when the rotation angle of the filter (a) was changed; and the relation between the rotation angle of the filter (a) and the fluctuation rate of the transmittance showed a sine curve. For the filter (b), although the transmittance fluctuated when the rotation angle of the filter (b) was changed, the fluctuation rate was smaller than that of the filter (a).

### (Observation of Polarization Dependence of Only Optical Function Layer)

The first optical function layer 42 alone was formed on a substrate different from the filters (a) and (b) to produce a filter for measurement. For the filter for measurement, the polarization dependence of the transmittance for vertically incident light was measured by the above-described procedure. As a result, the transmittance fluctuated when the rotation angle of the first optical function layer 42 was changed; and the relation between the rotation angle of the first optical function layer 42 and the fluctuation rate of the transmittance formed a sine curve. When the obtained sine curve was superposed on a sine curve having a phase angle shifted by 90°, the sine waves canceled each other. It is considered that the polarization dependence of the filter (b) was reduced because the first optical function layer 42 and the second optical function layer 43 were arranged such that the high transmittance axes, which are determined by the sine curves, intersect with each other at 90° and the sine waves were cancelled out.

For the filters (a) and (b), the reflectance of the front surface (the surface of the first optical function layer 42) and the back surface (the surface of the second optical function layer 43) was measured by the above-described procedure.

FIG. 27 is a graph illustrating the relation between the rotation angle of the filter (a) and the fluctuation rate of reflectance. The points on the graph are actually measured values, and the dotted lines are fitting curves fitted from the actually measured values. As shown in FIG. 27, the fitting curve of the front surface and the fitting curve of the back surface are substantially identical, and the high reflectance axes determined from the curves are also substantially identical.

FIG. 28 is a graph illustrating the relation between the rotation angle of the filter (b) and the fluctuation rate of reflectance. The points on the graph are actually measured values, and the dotted lines are fitting curves fitted from the actually measured values. As shown in FIG. 28, the fitting curve of the front surface and the fitting curve of the back surface have different phases by approximately 90°, and the fitting curves cancel each other when superposed. It can also be seen that the angle formed by the high reflectance axes, which are determined based on the curves, is approximately 90°.

In the present embodiment, the optical filter 40 having light transmittance characteristics or light reflectance characteristics in a predetermined wavelength range includes the first optical function layer 42 and the second optical function layer 43. The transmittance of the first optical function layer 42 and the transmittance of the second optical function layer 43 vary in the polarization direction of linearly polarized light at vertical incidence. The first optical function layer 42 and the second optical function layer 43 each have a high transmittance axis. The high transmittance axis is determined by a polarization direction in which the transmittance of linearly polarized light at perpendicular incidence is greatest. The first optical function layer 42 and the second optical function layer 43 are arranged such that the angle formed by the high transmittance axes thereof is within the range of 90°±30°.

Thus, the optical function layers cancel each other's the polarization dependence of transmittance for vertically incident light, so that the polarization dependence of the filter 40 can be reduced.

In the present embodiment, the substrate 41 that supports the first optical function layer 42 and the second optical function layer 43 is provided. The first optical function layer 42 is disposed on one surface of the substrate 41, and the second optical function layer 43 is disposed on the other surface of the substrate 41. Thus, the optical function layers cancel each other's the polarization dependence of transmittance for vertically incident light, so that the polarization dependence of the filter 40 can be reduced.

In the present embodiment, the substrate 41 that supports the first optical function layer 42 and the second optical function layer 43 is provided. The first optical function layer 42 and the second optical function layer 43 are layered on either surface of the substrate 41. Thus, the optical function layers cancel each other's the polarization dependence of transmittance for vertically incident light, so that the polarization dependence of the filter 40 can be reduced.

In the present embodiment, the first optical function layer 42 and the second optical function layer 43 satisfy the following Expression (1). Herein, a layer having a greater difference between the maximum transmittance and the average transmittance is defined as the first optical function layer 42, and a layer having a smaller difference therebetween is defined as the second optical function layer 43.

$$( T 2 max - T 2 ave ) / ( T 1 max - T 1 ave ) \geq 1 / 2 \qquad Expression ( 1 )$$

In the expression, T1max and T1ave represent the maximum transmittance and the average transmittance of the first optical function layer, respectively; and T2max and T2ave represent the maximum transmittance and the average transmittance of the second optical function layer, respectively.

Thus, the optical function layers cancel each other's the polarization dependence of transmittance for vertically incident light more effectively, so that the polarization dependence of the filter 40 can be reduced.

In the present embodiment, the filter 40 is a neutral density filter. Thus, in an apparatus equipped with the filter 40, the influence of polarization dependence can be reduced.

In the present embodiment, the filter 40 is a wavelength filter. Thus, in an apparatus equipped with the filter 40, the influence of polarization dependence can be reduced.

In the present embodiment, the filter satisfies the Expression (2). Herein, Tmin and Tmax represent the minimum value and the maximum value of the transmittance when the polarization direction of linearly polarized light at vertical incidence is changed.

$$( Tmin / Tmax ) \times 1 \; 00 [ \% ] \geq 95 [ \% ] \qquad Expression ( 2 )$$

Thus, in an apparatus equipped with the filter 40 having no polarization characteristics, the influence of polarization dependence can be reduced.

In the present embodiment, the optical filter 40 having light transmittance characteristics or light reflectance characteristics for a predetermined wavelength range includes the first optical function layer 42, the second optical function layer 43, and the substrate 41 that supports the first optical function layer 42 and the second optical function layer 43. The reflectance of the first optical function layer 42 and the reflectance of the second optical function layer 43 vary in the polarization direction of linearly polarized light at vertical incidence. The first optical function layer 42 is disposed on one surface of the substrate 41, and the second optical function layer 43 is disposed on the other surface of the substrate 41. The first optical function layer 42 and the second optical function layer 43 each have a high reflectance axis. The high reflectance axis is determined by a polarization direction in which the reflectance is greatest in perpendicular incidence of linearly polarized light. The first optical function layer 42 and the second optical function layer 43 are arranged such that the angle formed by the high reflectance axes thereof is within the range of 90°±30°. Thus, the optical function layers cancel each other's the polarization dependence of transmittance for vertically incident light, so that the polarization dependence of the filter 40 can be reduced.

In the present embodiment, the method of manufacturing the filter 40 includes the first layer formation step S1, the rotation step S2, and the second layer formation step S3. In the first layer formation step S1, the first optical function layer 42 is formed on the surface of the substrate 41 that is moving in a specific direction with respect to a target. The target is a material of the first optical function layer 42. In the rotation step S2, the substrate 41 is inverted such that the back surface of the substrate 41 faces the target as the material of the second optical function layer 43. When inverted, the substrate 41 is rotated in a specific direction on the center of the substrate 41 (the rotation center 91) within the range of 90°±30°. In the second layer formation step S3, the second optical function layer 43 is formed on the back surface of the substrate 41. Thus, the directionalities of the films caused by moving the substrate 41 only in a particular direction can be cancelled, and the polarization dependence of the filter 40 can be reduced.

In the present embodiment, the method of manufacturing the filter 40 includes the first layer formation step S1, the rotation step S2, and the second layer formation step S3. In the first layer formation step S1, the first optical function layer 42 is formed on the surface of the substrate 41 that moves in a specific direction with respect to a target. The target is a material of the first optical function layer 42. In the rotation step S2, the substrate 41 is rotated in a specific direction on the center of the substrate 41 (the rotation center 91) within the range of 90°±30°. In the second layer formation step S3, the second optical function layer 43 is formed on the first optical function layer 42. Thus, the directionalities of the films caused by moving the substrate 41 only in a particular direction can be cancelled, and the polarization dependence of the filter 40 can be reduced.

In the present embodiment, the method of manufacturing the filter 92, which includes the fifth optical function layer 93 having light transmittance characteristics or light reflectance characteristics for a predetermined wavelength range, includes a third layer formation step. In the third layer formation step, the fifth optical function layer 93 is formed on the surface of the substrate 41 while the substrate 41 is moving in a specific direction with respect to a target and rotating in the specific direction on the center of the substrate 41 (the rotation center 91). The target is a material of the fifth optical function layer 93. The above method avoids moving the substrate 41 only in a specific direction during film formation. Thus, the polarization dependence of the filter 92 can be reduced.

In the present embodiment, the optical filter unit 44 includes the first filter 45 and the second filter 46 that have a light transmittance characteristic or a light reflectance characteristic for a predetermined wavelength range. The first filter 45 includes the first substrate 47 and the first optical function layer 42. The first optical function layer 42 is supported by the first substrate 47. The transmittance of the first optical function layer 42 varies in the polarization direction of linearly polarized light at vertical incidence. The second optical filter 46 includes the second substrate 48 and the second optical function layer 43. The second optical function layer 43 is supported by the second substrate 48. The transmittance of the second optical function layer 43 varies in the polarization direction of linearly polarized light at vertical incidence. The first optical function layer 42 and the second optical function layer 43 each have a high transmittance axis. The high transmittance axis is determined by a polarization direction in which the transmittance of linearly polarized light at perpendicular incidence is greatest. The first filter 45 and the second filter 46 are disposed such that the angle formed by their high transmittance axes is within the range of 90°±30°. Thus, the optical function layers cancel each other's the polarization dependence of transmittance for vertically incident light, so that the polarization dependence of the filter unit 44 can be reduced.

In the present embodiment, the method of manufacturing the filter unit 44 includes the first optical filter production step S4, the second optical filter production step S5, and the placement step S6. In the first optical filter production step S4, the first filter 45 is produced by forming the first optical function layer 42 on the surface of the first substrate 47 that is moving in a specific direction with respect to a target. The target is the material of the first optical function layer 42. In the second optical filter production step S5, the second filter 46 is produced by forming the second optical function layer 43 on the surface of the second substrate 48 that is moving in a specific direction with respect to a target. The target is the material of the second optical function layer 43. In the placement step S6, the first filter 45 and the second filter 46 are arranged such that the angle formed by the specific direction in which the first substrate 47 moved and the specific direction in which the second substrate 48 moved is within the range of 90°±30°. Thus, the directionalities of the films caused by moving the first substrate 47 and the second substrate 48 only in a specific direction can be cancelled, and the polarization dependence of the filter unit 44 can be reduced.

In the present embodiment, the optical measurement apparatus 10 includes the filter 40 or the filter unit 44. Such a configuration can reduce measurement errors depending on polarization directions of measured light.

In the present embodiment, the optical measurement apparatus 10 includes the insertion-removal device that inserts the filter 40 or the filter unit 44 into the optical path of measured light and removes the filter 40 or the filter unit 44 from the optical path of the measured light. Such a configuration can reduce measurement errors caused by insertion and removal of the filter/the filter unit.

In the present embodiment, the optical measurement apparatus 10 measures the brightness or chromaticity of an measurement target. Such a configuration can reduce measurement errors depending on polarization directions of measured light.

The detailed configuration and operation of the components constituting the optical characteristic measurement apparatus can be appropriately modified without departing from the scope of the present invention. Although embodiments of the present invention have been described and shown in detail, the disclosed embodiments are made for purposes of illustration and example only and not limitation. The scope of the present invention should be interpreted by terms of the appended claims.

What is claimed is:

1. An optical filter having a light transmittance characteristic or a light reflectance characteristic for a predetermined wavelength range, the optical filter comprising:
a first optical function layer and a second optical function layer each having a transmittance that varies in a polarization direction of linearly polarized light at vertical incidence, wherein:
the first optical function layer and the second optical function layer each have a high transmittance axis, the high transmittance axis being determined by a polarization direction in which transmittance of linearly polarized light at vertical incidence is greatest, and
the first optical function layer and the second optical function layer are disposed such that an angle formed by the high transmittance axis of the first optical function layer and the high transmittance axis of the second optical function layer is within a range of 90°±30°.

2. The optical filter according to claim 1, further comprising a substrate that supports the first optical function layer and the second optical function layer, wherein:
the first optical function layer is disposed on a surface side of the substrate, and
the second optical function layer is disposed on another surface side of the substrate.

3. The optical filter according to claim 1, further comprising a substrate that supports the first optical function layer and the second optical function layer, wherein
the first optical function layer and the second optical function layer are layered on either surface side of the substrate.

4. The optical filter according to claim 1, wherein:
the first optical function layer is a layer having a greater difference between a maximum transmittance and an average transmittance, and the second optical function layer is a layer having a smaller difference between a maximum transmittance and an average transmittance, and
the optical filter satisfies an Expression (1).
$$( T 2 max - T 2 ave ) / ( T 1 max - T 1 ave ) \geq 1 / 2 \qquad Expression ( 1 )$$
where T1max and T1ave represent the maximum transmittance and the average transmittance of the first optical function layer, respectively, and T2max and T2ave represent the maximum transmittance and the average transmittance of the second optical function layer, respectively.

5. The optical filter according to claim 1, wherein the optical filter is a neutral density filter.

6. The optical filter according to claim 1, wherein the optical filter is a wavelength filter.

7. The optical filter according to claim 1, wherein the optical filter satisfies an Expression (2).
$$( Tmin / Tmax ) \times 100 [ \% ] \geq 95 [ \% ] \qquad Expression ( 2 )$$
where Tmin and Tmax represent a minimum value and a maximum value of transmittance, respectively, when a polarization direction of linearly polarized light at vertical incidence is changed.

8. An optical filter having a light transmittance characteristic or a light reflectance characteristic for a predetermined wavelength range, the optical filter comprising:
a first optical function layer and a second optical function layer having a reflectance that varies in a polarization direction of linearly polarized light at vertical incidence; and
a substrate that supports the first optical function layer and the second optical function layer,
wherein:
the first optical function layer is disposed on a surface side of the substrate,
the second optical function layer is disposed on another surface side of the substrate,
the first optical function layer and the second optical function layer each have a high reflectance axis, the high reflectance axis being determined by a polarization direction in which reflectance of linearly polarized light at vertical incidence is greatest, and
the first optical function layer and the second optical function layer are disposed such that an angle formed by the high reflectance axis of the first optical function layer and the high reflectance axis of the second optical function layer is within a range of 90°±30°.

9. A method of manufacturing the optical filter according to claim 1, the method comprising:
forming the first optical function layer on a front surface of a substrate while moving the substrate in a specific direction with respect to a first target, the first target being a material of the first optical function layer;
inverting the substrate so that a back surface of the substrate faces a second target, the second target being a material of the second optical function layer, and rotating the substrate on a center of the substrate as a rotation center in the specific direction within a range of 90°±30°; and
forming the second optical function layer on the back surface of the substrate.

10. A method of manufacturing the optical filter according to claim 1, the method comprising:
forming the first optical function layer on a front surface of a substrate while moving the substrate in a specific direction with respect to a first target, the first target being a material of the first optical function layer;
rotating the substrate on a center of the substrate as a rotation center in the specific direction within a range of 90°±30°; and
forming the second optical function layer on the first optical function layer.

11. A method of manufacturing an optical filter that includes a fifth optical function layer having a light transmittance characteristic or a light reflectance characteristic for a predetermined wavelength range, the method comprising:
forming the fifth optical function layer on a surface of a substrate while moving the substrate in a specific direction with respect to a target, the target being a material of the fifth optical function layer, and while rotating the substrate on a center of the substrate as a rotation center in the specific direction.

12. An optical filter unit comprising a first optical filter and a second optical filter that have a light transmittance characteristic or a light reflectance characteristic for a predetermined wavelength range, wherein:
the first optical filter includes a first substrate and a first optical function layer supported by the first substrate, the first optical function layer having a transmittance that varies in a polarization direction of linearly polarized light at vertical incidence,
the second optical filter includes a second substrate and a second optical function layer supported by the second substrate, the second optical function layer having a transmittance that varies in a polarization direction of linearly polarized light at vertical incidence,
the first optical function layer and the second optical function layer each have a high transmittance axis, the high transmittance axis being determined by a polarization direction in which transmittance of linearly polarized light at vertical incidence is greatest, and
the first optical filter and the second optical filter are disposed such that an angle formed by the high transmittance axis of the first optical filter and the high transmittance axis of the second optical filter is within a range of 90°±30°.

13. A method of manufacturing the optical filter unit according to claim 12, the method comprising:
producing the first optical filter by forming the first optical function layer on a surface of the first substrate that moves in a specific direction with respect to a first target, the first target being a material of the first optical function layer;
producing the second optical filter by forming the second optical function layer on a surface of a second substrate that moves in a specific direction with respect to a second target, the second target being a material of the second optical function layer; and
disposing the first optical filter and the second optical filter such that an angle formed by the specific direction in which the first substrate moved and the specific direction in which the second substrate moved is within a range of 90°±30°.

14. An optical measurement apparatus comprising the optical filter according to claim 1.

15. An optical measurement apparatus comprising the optical filter unit according to claim 12.

16. The optical measurement apparatus according to claim 14, comprising an insertion-removal device configured to insert or remove the optical filter into or from an optical path of light to be measured.

17. The optical measurement apparatus according to claim 15, comprising an insertion-removal device configured to insert or remove the optical filter unit into or from an optical path of light to be measured.

18. The optical measurement apparatus according to claim 14, configured to measure brightness or chromaticity of a measurement target.

19. The optical measurement apparatus according to claim 15, configured to measure brightness or chromaticity of a measurement target.
